(19) United States
(12) Patent Application Publication
(10) Pub. No.: US 2025/0324835 A1
(43) Pub. Date: Oct. 16, 2025

(54) DISPLAY DEVICE, METHOD OF MANUFACTURING THE DISPLAY DEVICE AND ELECTRONIC DEVICE INCLUDING THE DISPLAY DEVICE

(71) Applicant: SAMSUNG DISPLAY CO., LTD., Yongin-si (KR)

(72) Inventors: SUNGBAE JU, Yongin-si (KR); SO-RA KIM, Yongin-si (KR); JEONG-SEON KIM, Yongin-si (KR); BOBAE SONG, Yongin-si (KR); AHYEON LEE, Yongin-si (KR)

(21) Appl. No.: 18/990,139

(22) Filed: Dec. 20, 2024

(30) Foreign Application Priority Data
Apr. 11, 2024 (KR) 10-2024-0048793

(51) Int. Cl. H10H 29/49; H10H 29/01

(52) U.S. Cl. CPC H10H 29/49; H10H 29/012

(57) ABSTRACT

A display device includes: a light emitting diode; a transistor disposed on the light emitting diode and electrically connected to the light emitting diode; and a substrate disposed below the transistor, and including a central area and a hole area that is adjacent to the central area, wherein the substrate includes an organic material and a first substrate, in which first holes are disposed in the hole area.

### CROSS-REFERENCE TO RELATED APPLICATION

This application claims priority under 35 U.S.C. § 119 to Korean Patent Application No. 10-2024-0048793, filed on Apr. 11, 2024, the disclosure of which is incorporated by reference herein in its entirety.

### TECHNICAL FIELD

A present disclosure relates to a display device, a method of manufacturing the display device and an electronic device including the display device. More specifically, the present disclosure relates to a display device that provides visual information, a method of manufacturing the display device and an electronic device including the display device.

### DISCUSSION OF THE RELATED ART

Recently, foldable displays, which may replace a glass substrate of display devices with a polyimide substrate and may maintain display performance even when bent or folded, are rapidly emerging as the next-generation display.

Generally, to manufacture display devices such as foldable displays, rollable displays, or stretchable displays, the polyimide substrate may be adhered to a carrier substrate. The carrier substrate should be separated from the polyimide substrate. However, if the carrier substrate does not smoothly separate from the polyimide substrate, the polyimide substrate may be damaged, or the detachment process may need to be repeated, leading to a reduced process yield. Accordingly, various methods of manufacturing display devices are currently under development.

### SUMMARY

According to an embodiment of the present disclosure, a display device includes: a light emitting diode; a transistor disposed below the light emitting diode and electrically connected to the light emitting diode; and a substrate disposed below the transistor, and including a central area and a hole area that is adjacent to the central area, wherein the substrate includes an organic material and a first substrate, in which first holes are disposed in the hole area.

In an embodiment of the present disclosure, the hole area is adjacent to an edge of the substrate.

In an embodiment of the present disclosure, the substrate further includes a first barrier layer disposed on the first substrate and filling the first holes.

In an embodiment of the present disclosure, the substrate further includes: a second substrate disposed on the first barrier layer, and including an organic material, wherein the second substrate has second holes disposed in the hole area; and a second barrier layer disposed on the second substrate and filling the second holes.

In an embodiment of the present disclosure, the second holes expose at least a portion of the first barrier layer.

In an embodiment of the present disclosure, the first holes and the second holes do not overlap each other in a plan view.

In an embodiment of the present disclosure, at least one of the first holes partially overlaps at least one of the second holes in a plan view.

In an embodiment of the present disclosure, at least one of the first holes entirely overlaps at least one of the second holes in a plan view.

In an embodiment of the present disclosure, each of the first holes has a first planar area, and each of the second holes has a second planar area, wherein the first planar area and the second planar area are a same as each other.

In an embodiment of the present disclosure, each of the first holes has a first planar area, and each of the second holes has a second planar area, wherein the first planar area and the second planar area are different from each other.

In an embodiment of the present disclosure, the first planar area is greater than the second planar area.

In an embodiment of the present disclosure, the first planar area is less than the second planar area.

In an embodiment of the present disclosure, each of the first holes and the second holes has a circular planar shape.

In an embodiment of the present disclosure, the hole area includes: first to fourth corner areas extending from a corner of the central area; a first connection area connecting the first corner area and the second corner area to each other; a second connection area connecting the second corner area and the third corner area to each other; a third connection area connecting the third corner area and the fourth corner area to each other; and a fourth connection area connecting the fourth corner area and the first corner area to each other.

In an embodiment of the present disclosure, the first holes and the second holes are located in the first to fourth corner areas.

In an embodiment of the present disclosure, the first holes and the second holes are located in the first to fourth connection areas.

According to an embodiment of the present disclosure, a method of manufacturing the display device includes: forming a first substrate including an organic material, a central area, and a hole area at least partially surrounding the central area on a carrier substrate; forming first holes in the hole area of the first substrate; forming a first barrier layer in the first holes and on the first substrate; forming a second substrate, which includes an organic material, on the first barrier layer; forming second holes, which expose the first barrier layer, in the second substrate; and forming a second barrier layer in the second holes and on the second substrate.

In an embodiment of the present disclosure, the method further includes: after forming the second barrier layer, separating the first substrate and the carrier substrate from each other.

In an embodiment of the present disclosure, in forming the first holes and forming the second holes, each of the first holes and the second holes is formed through an etching process.

In an embodiment of the present disclosure, the etching process is a dry etching process.

According to an embodiment of the present disclosure, an electronic device includes a housing and a display device stored in the housing, that displays an image, and including a light emitting diode, a transistor disposed below the light emitting diode and electrically connected to the light emitting diode, and a substrate disposed below the transistor, and including a central area and a hole area that is adjacent to the central area, wherein the substrate includes an organic material and a first substrate, in which first holes are disposed in the hole area.

### BRIEF DESCRIPTION OF THE DRAWINGS

The above and other features of the present disclosure will become more apparent by describing in detail embodiments thereof, with reference to the accompanying drawings, in which:

FIG. 1 is a perspective view showing a display device according to an embodiment of the present disclosure.

FIG. 2 is a cross-sectional view taken along line I-I′ of FIG. 1.

FIG. 3 is a cross-sectional view showing the display panel of FIG. 2.

FIG. 4 is a plan view showing an embodiment of the substrate of FIG. 3.

FIG. 5 is an enlarged plan view showing an example of area A of FIG. 4.

FIG. 6 is a cross-sectional view taken along line II-II' of FIG. 5.

FIGS. 7, 8, 9, 10, 11, 12, 13, 14, 15, 16, 17 and 18 are views showing a method for manufacturing the substrate of FIG. 6, according to an embodiment of the present disclosure.

FIG. 19 is an enlarged plan view of area A of FIG. 4, according to an embodiment of the present disclosure.

FIG. 20 is a cross-sectional view taken along line III-III' of FIG. 19.

FIG. 21 is an enlarged plan view of area A of FIG. 4, according to an embodiment of the present disclosure.

FIG. 22 is an enlarged plan view of area A of FIG. 4, according to an embodiment of the present disclosure.

FIG. 23 is an enlarged plan view of the substrate of FIG. 3, according to an embodiment of the present disclosure.

FIG. 24 is an enlarged plan view of the substrate of FIG. 3, according to an embodiment of the present disclosure.

FIG. 25 is an enlarged plan view of the substrate of FIG. 3, according to an embodiment of the present disclosure.

FIG. 26 is an enlarged plan view of the substrate of FIG. 3, according to an embodiment of the present disclosure.

FIG. 27 is an enlarged plan view of area A of FIG. 4, according to an embodiment of the present disclosure.

FIG. 28 is a cross-sectional view taken along line IV-IV' of FIG. 15.

FIG. 29 is a block diagram showing an electronic device according to an embodiment of the present disclosure.

FIG. 30 is a perspective view showing the electronic device according to an embodiment of the present disclosure.

### DETAILED DESCRIPTION OF THE EMBODIMENTS

Illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be substantially perpendicular to the first direction D1. In addition, a third direction D3 may be a normal direction of the plane. For example, the third direction D3 may be substantially perpendicular to the plane that is formed by the first direction D1 and the second direction D2.

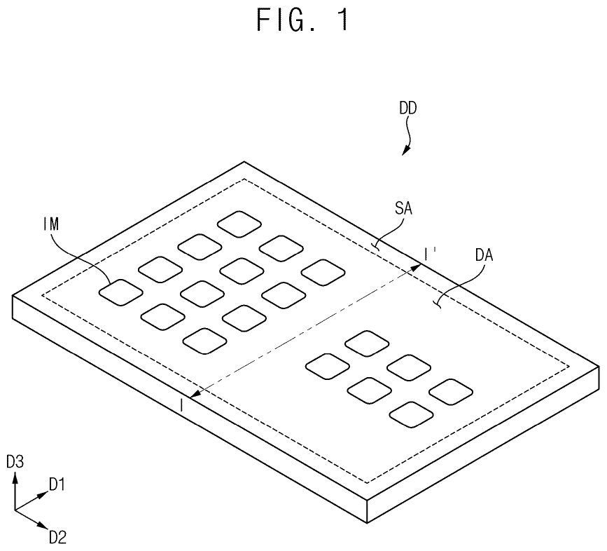

FIG. 1 is a perspective view showing a display device according to an embodiment of the present disclosure.

Referring to FIG. 1, the display device DD may include a display area DA and a peripheral area SA. The display area DA may be adjacent to the peripheral area SA. For example, the display DA may be surrounded by the peripheral area SA.

The display area DA may be an area that may display an image by generating light or adjusting a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM. Users may receive information from the display device DD through the plurality of images IM.

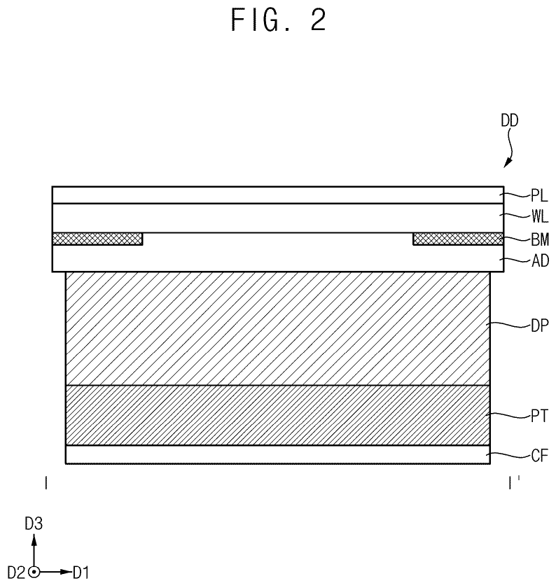

FIG. 2 is a cross-sectional view taken along line I-I′ of FIG. 1.

Referring to FIG. 2, the display device DD may include a cover film CF, a plate PT, a display panel DP, an adhesive member AD, a light blocking member BM, a window layer WL, and a protection film PL.

The cover film CF may be disposed in a back end of the display device DD to protect the display device DD from external impacts. For example, the cover film CF may form a back surface of the display device DD. For example, the cover film CF may include at least one of polyurethane (PU), thermoplastic polyurethane (TPU), silicone (Si), and/or polydimethylacrylamide (PDMA). These may be used alone or in combination with each other. However, embodiments of the present disclosure are not necessarily limited thereto.

The plate PT may be disposed on the cover film CF. The plate PT may support the display panel DP and may protect the display device DD from external impacts. For example, the plate PT may maintain the display panel DP in a relatively flat state even when an external force is applied from outside the display device DD. The plate PT may include a rigid or semi-rigid material. For example, the plate PT may include at least one of iron, chromium, carbon, nickel, silicon, manganese, and/or molybdenum. These may be used alone or in combination with each other. However, embodiments of the present disclosure are not necessarily limited thereto.

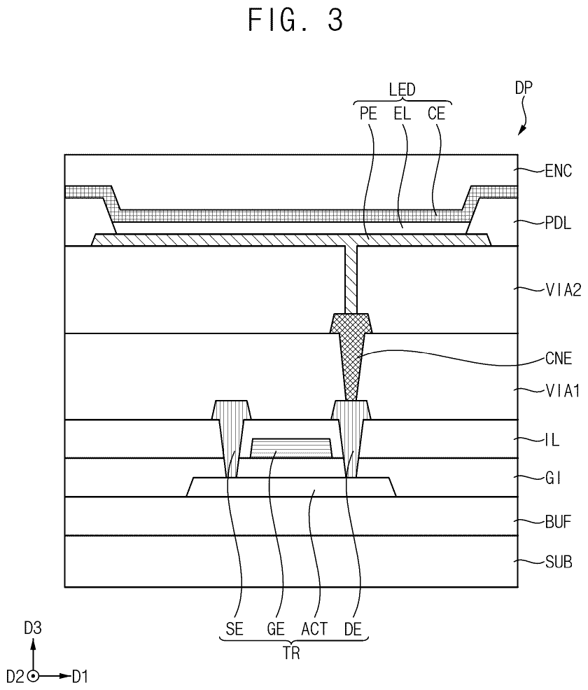

The display panel DP may be disposed on the plate PT. The display panel DP may receive electrical signals and emit light so that the display device DD may provide visual information to users. For example, the display panel DP may be either an organic light emitting display panel or an inorganic light emitting display panel. However, embodiments of the present disclosure are not necessarily limited thereto. The display panel DP will be described in detail later with reference to FIG. 3.

The adhesive member AD may be disposed on the display panel DP. The adhesive member AD may adhere the display panel DP and components disposed thereon to each other. For example, the adhesive member AD may adhere the display panel DP and the window layer WL to each other. For example, the adhesive member AD may include pressure sensitive adhesive (PSA), optical clear adhesive (OCA), or optical clear resin (OCR). However, embodiments of the present disclosure are not necessarily limited thereto.

The light blocking member BM may be disposed on the adhesive member AD. The light blocking member BM may provide convenience to users by blocking light that is coming from a rear of the display device DD. For example, the light blocking member BM may include a light absorbing material. For example, the light blocking member BM may include an inorganic black pigment or an organic black pigment. The inorganic black pigment may be carbon black, and the organic black pigment may include at least one of Lactam Black, Perylene Black, and Aniline Black. These may be used alone or in combination with each other. However, embodiments of the present disclosure are not necessarily limited thereto.

The window layer WL may be disposed on the adhesive member AD. The window layer WL may include a substantially transparent material. For example, the window layer WL may be glass or plastic. However, embodiments of the present disclosure are not necessarily limited thereto.

The protective film PL may be disposed on the window layer WL. The protective film PL may protect the window layer WL from, for example, front impacts, scratches, etc. The protective film PL may include a single-layer and/or multi-layer structure. For example, the protective film PL may include at least one of a base layer, a hard coating layer, a low refractive index layer, and an anti-fingerprint layer. However, embodiments of the present disclosure are not necessarily limited thereto.

FIG. 3 is a cross-sectional view showing the display panel of FIG. 2.

Referring to FIGS. 1 and 3, the display panel DP may include a substrate SUB, a buffer layer BUF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include, for example, a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper part of the substrate SUB. The buffer layer BUF may include an inorganic insulating material.

The active layer ACT may be disposed on the buffer layer BUF. The active layer ACT may include, for example, an oxide semiconductor, a silicon semiconductor, an organic semiconductor, etc. For example, the oxide semiconductor may include at least one of indium (In), gallium (Ga), tin (Sn), zirconium (Zr), vanadium (V), hafnium (Hf), cadmium (Cd), germanium (GE), chromium (Cr), titanium (Ti), and/or zinc (Zn). For example, silicon semiconductor may include amorphous silicon, polycrystalline silicon, etc. The active layer ACT may include a source region, a drain region, and a channel region located between the source region and the drain region.

The gate insulating layer GI may be disposed on the buffer layer BUF. For example, the gate insulating layer GI may be disposed on the buffer layer BUF and cover the active layer ACT. The gate insulating layer GI may include an inorganic insulating material. In an embodiment of the present disclosure, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (PT), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy including aluminum, an alloy including silver, an alloy including copper, an alloy including molybdenum, aluminum nitride (AIN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. Optionally, the gate electrode GE may have a single-layer structure or a multi-layer structure including a plurality of conductive layers.

The interlayer insulating layer IL may be disposed on the gate electrode GE. For example, the interlayer insulating layer IL may be disposed on the gate insulating layer GI and cover the gate electrode GE. The interlayer insulating layer IL may include an inorganic insulating material.

The source electrode SE and the drain electrode DE may be disposed on the interlayer insulating layer IL. The source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material.

The first via layer VIA1 may be disposed on the source electrode SE and the drain electrode DE. For example, the first via layer VIA1 may be disposed on the interlayer insulating layer IL and cover the source electrode SE and the drain electrode DE on the interlayer insulating layer IL. The first via layer VIA1 may include an organic insulating material. In an embodiment of the present disclosure, the first via layer VIA1 may be formed in the display area DA and a portion of the peripheral area SA that is adjacent to the display area DA.

The connection electrode CNE may be disposed on the first via layer VIA1. The connection electrode CNE may transmit a signal that is transmitted from the transistor TR to the light emitting diode LED. For example, the connection electrode CNE may include metal, alloy, metal nitride, conductive metal oxide, transparent conductive material, etc. These may be used alone or in combination with each other. However, embodiments of the present disclosure are not necessarily limited thereto.

The second via layer VIA2 may be disposed on the connection electrode CNE. For example, the second via layer VIA2 may be disposed on the first via layer VIA1 and cover the connection electrode CNE. The second via layer VIA2 may include substantially a same or a same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. For example, the light emitting layer EL may be disposed within an opening that is formed in the pixel defining layer PDL. For example, the light emitting layer EL may be at least partially surrounded by the pixel defining layer PDL. The light emitting layer EL may include at least one of organic light emitting materials and/or quantum dots. However, embodiments of the present disclosure are not necessarily limited thereto.

The common electrode CE may be disposed on the light emitting layer EL. The common electrode CE may also be disposed on the pixel defining layer PDL. For example, the common electrode CE may be continuously disposed on the light emitting layer EL and the pixel defining layer PDL. The common electrode CE may include a conductive material. The light emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment of the present disclosure, the inorganic encapsulation layer and the organic encapsulation layer may be alternately disposed on each other. For example, the organic encapsulation layer may include a cured polymer such as polyacrylate, epoxy resin, or silicone resin. For example, the inorganic thin film may include silicon oxide, silicon nitride, silicon carbide, aluminum oxide, tantalum oxide, hafnium oxide, zirconium oxide, titanium oxide, etc.

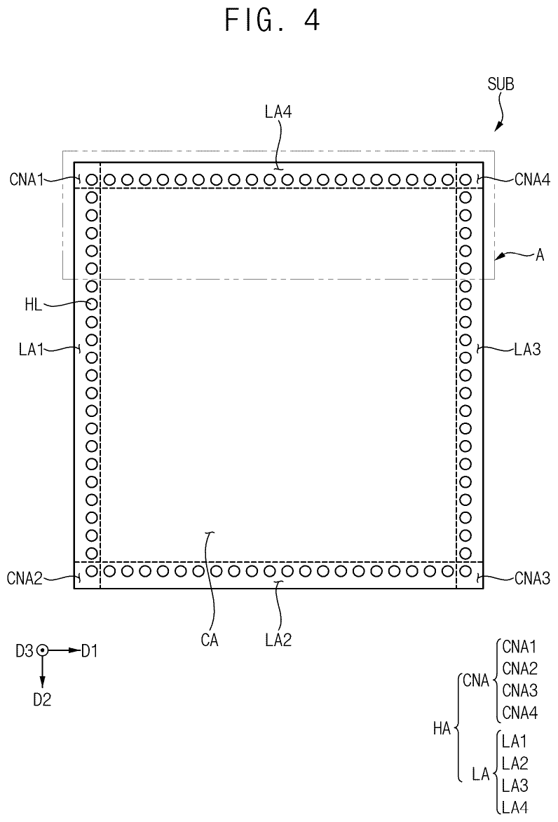

FIG. 4 is a plan view showing an embodiment of the substrate of FIG. 3.

Referring to FIGS. 3 and 4, the substrate SUB may include a central area CA and a hole area HA at least partially surrounding the central area CA. For example, the hole area HA may be provided adjacent to an edge of the substrate SUB.

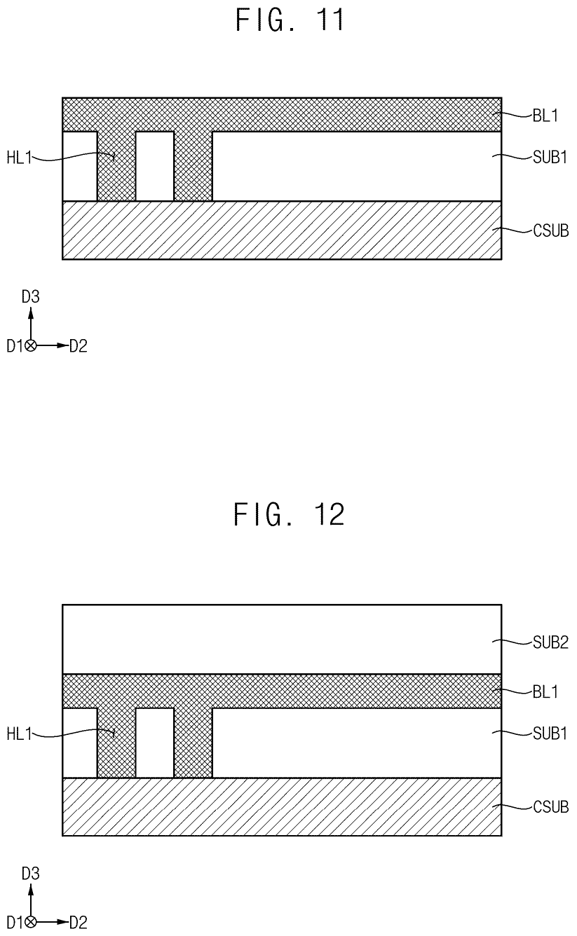

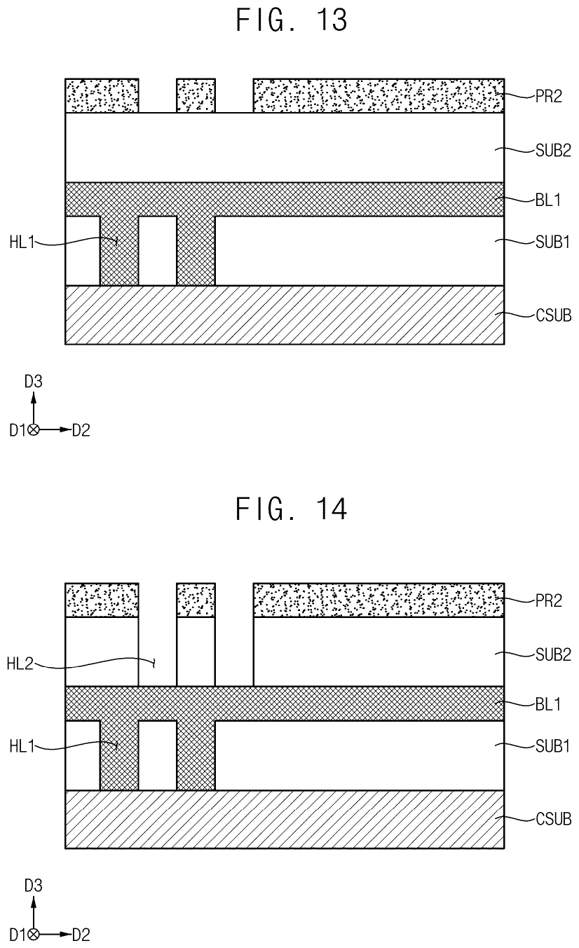

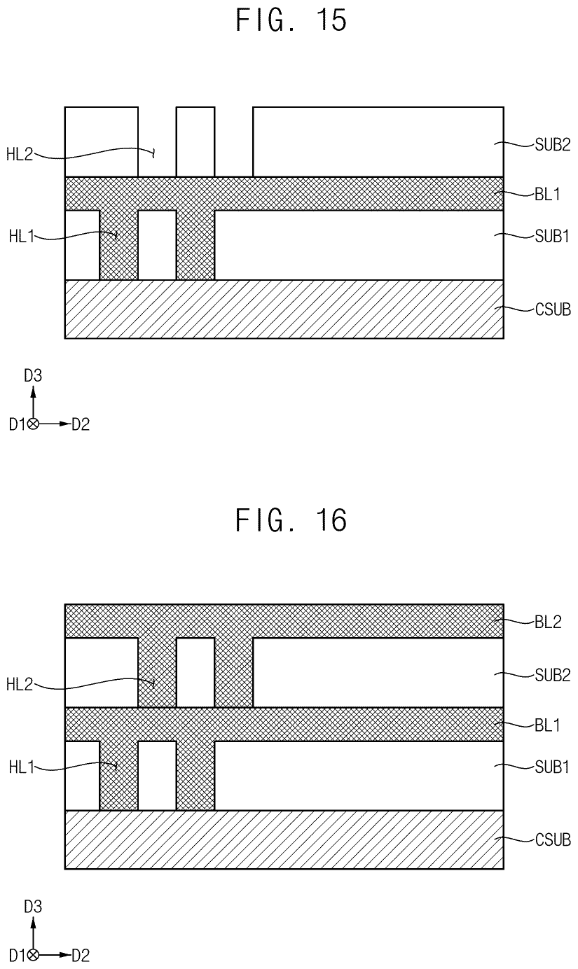

A plurality of holes HL may be disposed in the hole area HA. The holes HL may be disposed in the hole area HA along the first direction D1 and/or the second direction D2. In FIG. 4, the holes HL are arranged throughout the hole area HA, but the embodiment of the present disclosure is not necessarily limited thereto. For example, the holes HL may be formed only in a portion of the hole area HA. This will be described later with reference to FIGS. 11 to 14.

In an embodiment of the present disclosure, the hole area HA may include corner areas CNA and connection areas LA. The corner areas CNA may extend from a corner of the central area CA. The corner areas CNA may include first, second, third, and fourth corner areas CNA1, CNA2, CNA3, and CNA4. The connection areas LA may include first, second, third, and fourth connection areas LA1, LA2, LA3, and LA4.

For example, the first, second, third, and fourth corner areas CNA1, CNA2, CNA3, and CNA4 may be located one by one in a counterclockwise direction at a corresponding corner of the substrate SUB. For example, the second corner area CNA2 may be located to be spaced apart from the first corner area CNA1 in the second direction D2. The third corner area CNA3 may be located to be spaced apart from the second corner area CNA2 in the first direction D1. The fourth corner area CNA4 may be located to be spaced apart from the third corner area CNA3 in a direction opposite to the second direction D2. The first corner area CNA1 may be located to be spaced apart from the fourth corner area CNA4 in a direction opposite to the first direction D1.

The first connection area LA1 may connect the first corner area CNA1 and the second corner area CNA2 to each other and may extend in the second direction D2. The second connection area LA2 may connect the second corner area CNA2 and the third corner area CNA3 to each other and may extend in the first direction D1. The third connection area LA3 may connect the third corner area CNA3 and the fourth corner area CNA4 to each other and may extend in the second direction D2. The fourth connection area LA4 may connect the fourth corner area CNA4 and the first corner area CNA1 to each other and may extend in the first direction D1.

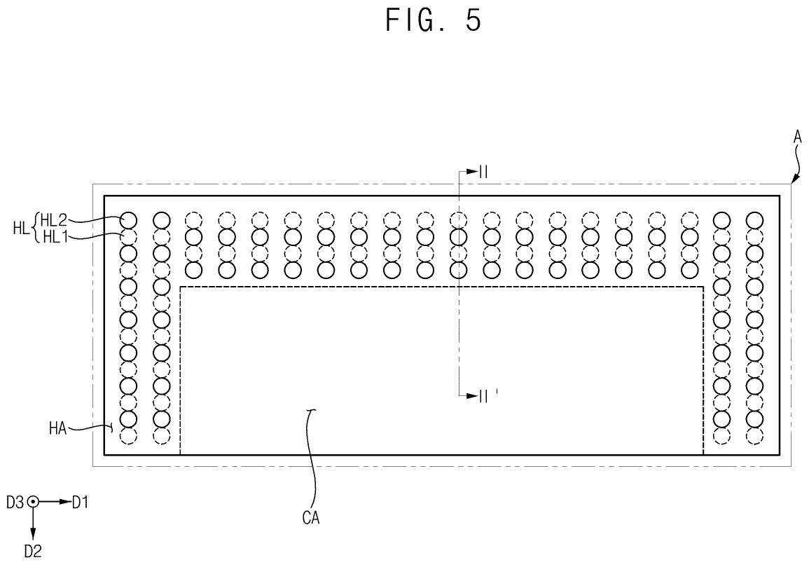

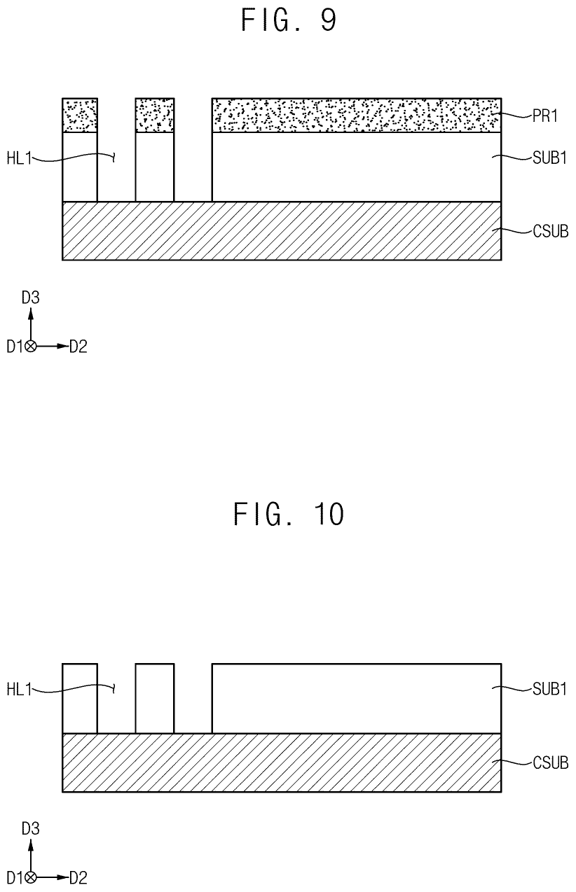

The substrate SUB may have a multilayer structure. For example, the substrate SUB may have a two-layer structure including one organic material layer and one inorganic material layer. For another example, the substrate SUB may have a multilayer structure including at least two organic layers and at least one inorganic layer. The substrate SUB will be described in detail later with reference to FIGS. 5 to 14.

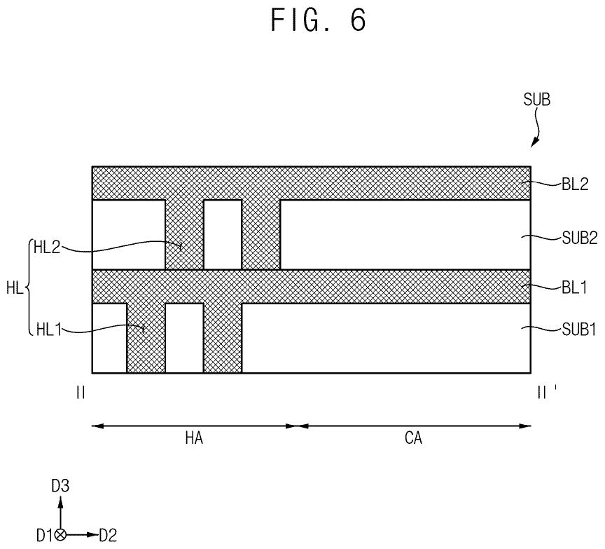

FIG. 5 is an enlarged plan view showing an example of area A of FIG. 4. FIG. 6 is a cross-sectional view taken along line II-II' of FIG. 5. Specifically, the substrate SUB in FIGS. 5 and 6 shows an example of the substrate SUB having a multilayer structure.

Referring to FIGS. 5 and 6, in an embodiment of the present disclosure, the substrate SUB may include a first substrate SUB1, a first barrier layer BL1, a second substrate SUB2, and a second barrier layer BL2.

Each of the first substrate SUB1 and the second substrate SUB2 may include an organic material. For example, each of the first substrate SUB1 and the second substrate SUB2 may include a polyimide-based resin. However, embodiments of the present disclosure are not necessarily limited thereto. Each of the first substrate SUB1 and the second substrate SUB2 may include at least one of acrylic resin, methacrylic resin, polyisoprene, vinyl resin, epoxy resin, urethane resin, cellulose resin, siloxane resin, polyamide resin, and/or perylene-based resin.

In an embodiment of the present disclosure, first holes HL1 may be disposed in an area where the first substrate SUB1 and the hole area HA overlap each other. Second holes HL2 may be disposed in an area where the second substrate SUB2 and the hole area HA overlap each other. That is, in an embodiment of the present disclosure, the holes HL located in the hole region HA of the substrate SUB described with reference to FIG. 4 may be a set of the first holes HL1, which are disposed in the first substrate SUB1, and the second holes HL2, which are disposed in the second substrate SUB2.

The first barrier layer BL1 may be disposed on the first substrate SUB1. The first barrier layer BL1 may fill the first holes HL1 of the first substrate SUB1. The first barrier layer BL1 may include an inorganic material such as an oxide or a nitride, an organic material, or an organic-inorganic composite, and may have a single-layer or multi-layer structure of an inorganic material and an organic material. However, embodiments of the present disclosure are not necessarily limited thereto.

The second substrate SUB2 may be disposed on the first barrier layer BL1. At least a portion of the first barrier layer BL1 may be exposed by the second holes HL2 of the second substrate SUB2.

The second barrier layer BL2 may be disposed on the second substrate SUB2. The second barrier layer BL2 may fill the second holes HL2 of the second substrate SUB2. The second barrier layer BL2 may include an inorganic material such as oxide or nitride, an organic material, or an organic-inorganic composite, and may have a single-layer or multi-layer structure of an inorganic material and an organic material. However, embodiments of the present disclosure are not necessarily limited thereto.

In an embodiment of the present disclosure, as shown in FIG. 5, the first holes HL1 and the second holes HL2 might not overlap each other in a plan view. For example, the first holes HL1 and the second holes HL2 may be defined to alternate with each other in the second direction D2 in a plan view. However, the present disclosure is not necessarily limited thereto. For example, the first holes HL1 and the second holes HL2 may be defined to alternate with each other in the first direction D1 in a plan view, and in both the first direction D1 and the second direction D2. As the first holes HL1 and the second holes HL2 are alternately located in the hole area HA of the substrate SUB, a direction of stress that may occur in the first substrate SUB1 and a direction of stress that may occur on the substrate SUB2 may be different from each other. Accordingly, curling of the substrate SUB may be prevented or reduced.

In an embodiment of the present disclosure, a planar shape of the holes HL may be circular. For example, a planar shape of each of the first holes HL1 and the second holes HL2 may be circular. However, embodiments of the present disclosure are not necessarily limited thereto. For example, a planar shape of the holes HL may be oval, polygonal, etc.

Each of the first holes HL1 may have a first planar area in a plan view. Each of the second holes HL2 may have a second planar area in a plan view. In an embodiment of the present disclosure, the first planar area of each of the first holes HL1 may be substantially the same or the same as the second planar area of each of the second holes HL2. However, the present disclosure is not necessarily limited thereto.

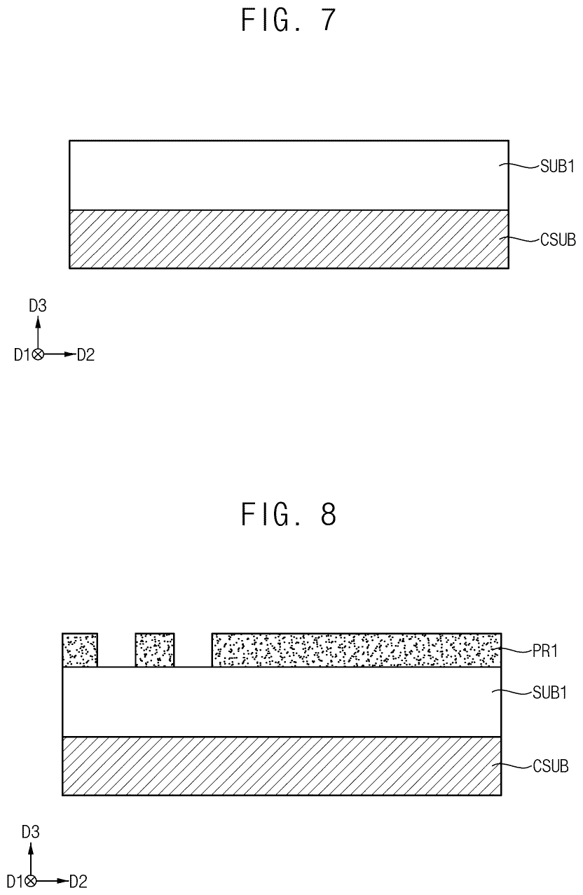

FIGS. 7 to 18 are views showing a method for manufacturing the substrate of FIG. 6, according to an embodiment of the present disclosure.

Referring to FIGS. 2 and 7, the first substrate SUB1 may be formed on the carrier substrate CSUB. The first substrate SUB1 may be formed by depositing an organic material that includes polyimide on the carrier substrate CSUB.

The carrier substrate CSUB may temporarily support components that are included in the display device DD when the display device DD is formed. The carrier substrate CSUB may include a material with excellent rigidity and heat resistance. For example, the carrier substrate CSUB may include at least one of glass and/or quartz. These may be used alone or in combination with each other. However, embodiments of the present disclosure are not necessarily limited thereto.

Referring further to FIGS. 8 to 10, the first photoresist PR1 may be disposed on the first substrate SUB1. At least a portion of the first photoresist PR1 may be removed through an exposure process. For example, at least a portion of the first photoresist PR1 may expose at least a portion of the first substrate SUB1 through an exposure process. An etching process may be performed on an exposed upper surface of the first substrate SUB1 through the first photoresist PR1 that is patterned through the exposure process. For example, the etching process may be a dry etching process. However, embodiments of the present disclosure are not necessarily limited thereto.

After going through the etching process, the first holes HL1 may be formed in the first substrate SUB1. After the first holes HL1 are formed in the first substrate SUB1, the first photoresist PR1 may be removed.

Referring further to FIG. 11, the first barrier layer BL1 may be formed on the first substrate SUB1. The first barrier layer BL1 may be formed by depositing an inorganic material on the first substrate SUB1. However, the present disclosure is not necessarily limited thereto. For example, the first barrier layer BL1 may be formed on the first substrate SUB1 while filling the first holes HL1.

Referring further to FIG. 12, the second substrate SUB2 may be formed on the first barrier layer BL1. The second substrate SUB2 may be formed by depositing an organic material that includes polyimide on the first barrier layer BL1.

Referring further to FIGS. 13, 14, and 15, the second photoresist PR2 may be applied on the second substrate SUB2. At least a portion of the second photoresist PR2 may be removed through an exposure process. That is, at least a portion of the second photoresist PR2 may expose at least a portion of the second substrate SUB2 through an exposure process.

An etching process may be performed on an exposed upper surface of the second substrate SUB2 through the second photoresist PR2 that is patterned through the exposure process. Accordingly, at least a portion of the second substrate SUB2 may be removed through the etching process. That is, the second holes HL2 may be formed in the second substrate SUB2. Thereafter, the second photoresist PR2 may be removed.

Referring further to FIG. 16, the second barrier layer BL2 may be formed on the second substrate SUB2. The second barrier layer BL2 may be formed by depositing an inorganic material on the second substrate SUB2. However, the present disclosure is not necessarily limited thereto. Specifically, the second barrier layer BL2 may be formed on the second substrate SUB2 while filling the second holes HL2.

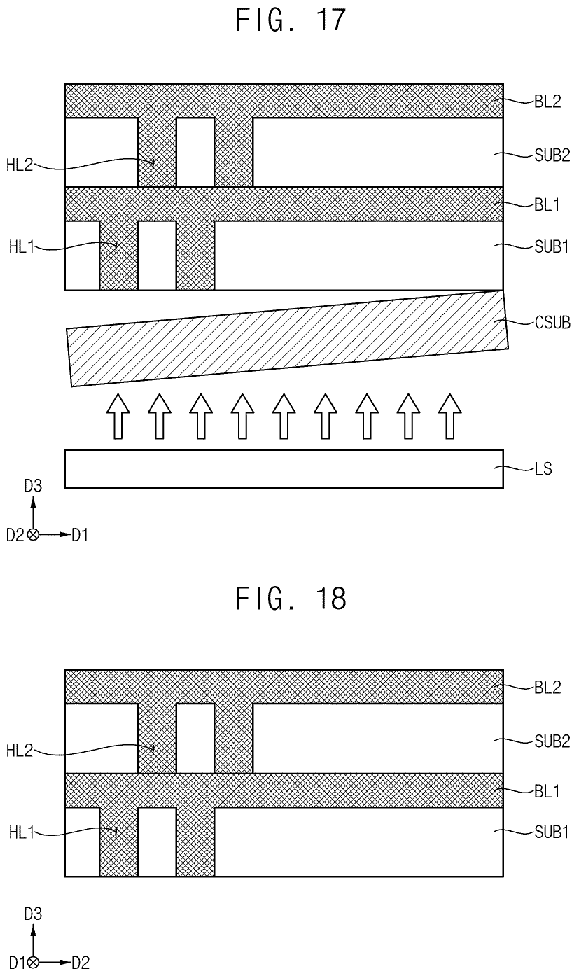

Referring further to FIGS. 17 and 18, the carrier substrate CSUB may be removed after the second holes HL2 are formed in the second substrate SUB2. Specifically, the carrier substrate CSUB may be removed and separated from the first substrate SUB1. For example, the carrier substrate CSUB may be separated from the first substrate SUB1 through a laser, etc. that is emitted from a laser device LS. As a result, the substrate SUB shown in FIG. 18 may be formed.

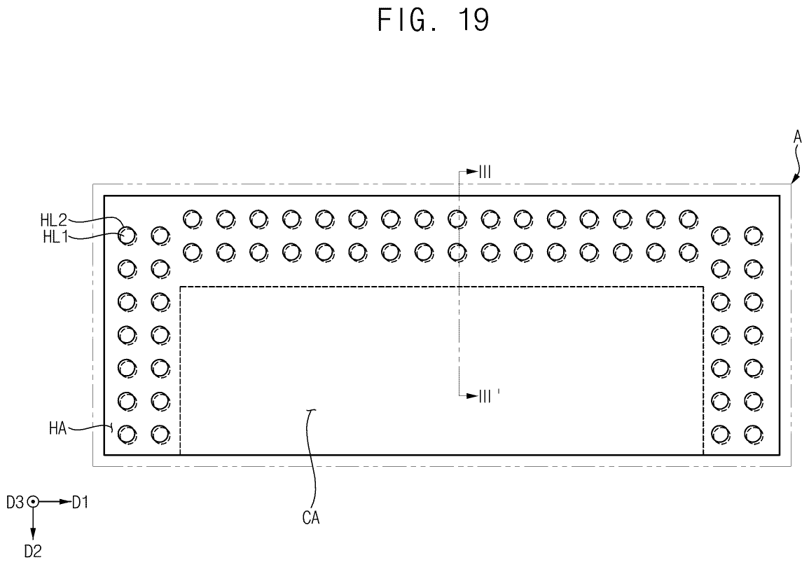

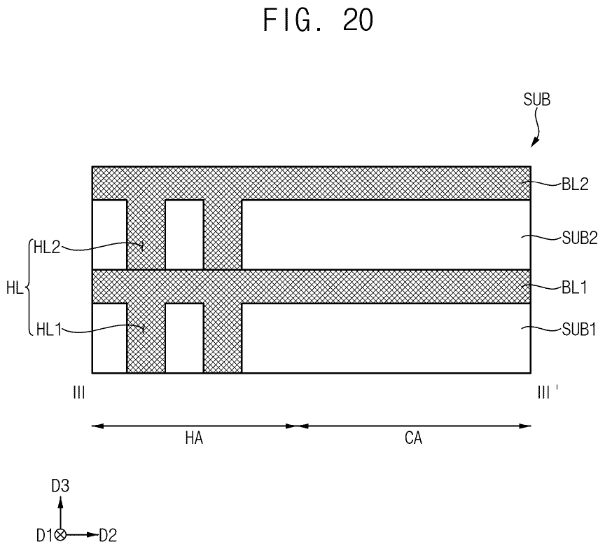

FIG. 19 is an enlarged plan view of area A of FIG. 4, according to an embodiment of the present disclosure. FIG. 20 is a cross-sectional view taken along line III-III′ of FIG. 19.

A description referring to FIGS. 19 and 20 may differ from a description referring to FIGS. 5 and 6 only in the positions where the first holes HL1 and the second holes HL2 are provided. Therefore, overlapping descriptions may be omitted or simplified.

In addition, a method of manufacturing the substrate SUB according to the embodiment referring to FIGS. 19 and 20 may be substantially a same as the manufacturing method described with reference to FIGS. 7 to 18 except for a difference in positions where the first holes HL1 and the second holes HL2 are provided. Accordingly, a method of manufacturing the substrate SUB according to the embodiment referring to FIGS. 19 and 20 may be omitted.

Referring to FIGS. 19 and 20, at least one of the first holes HL1 and at least one of the second holes HL2 may overlap each other in a plan view.

In an embodiment of the present disclosure, as shown in FIG. 19, at least one of the first holes HL1 may entirely overlap at least one of the second holes HL2 in a plan view. For example, the first holes HL1 and the second holes HL2 may correspond to each other in a one-to-one manner, and any one of the first holes HL1 may entirely overlap a corresponding second hole of the second holes HL2 in a plan view.

However, the present disclosure is not necessarily limited thereto, and in an embodiment of the present disclosure, at least one of the first holes HL1 may partially overlap with at least one of the second holes HL2 in a plan view. For example, the first holes HL1 and the second holes HL2 may correspond to each other in a one-to-one manner, and one of the first holes HL1 may partially overlap a corresponding second hole of the second holes HL2 in a plan view.

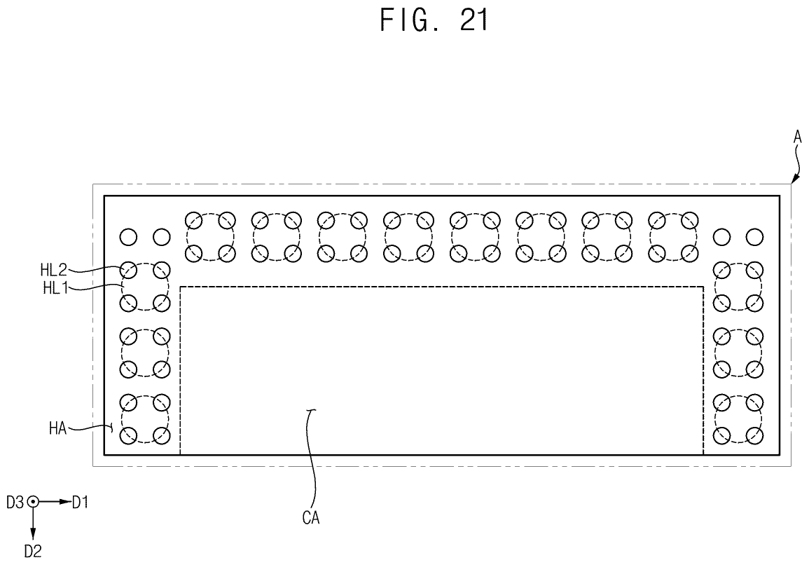

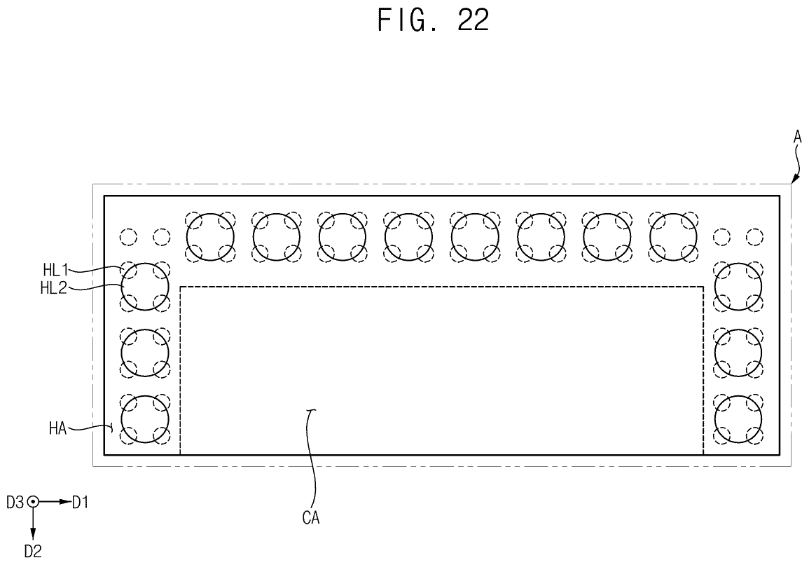

FIG. 21 is an enlarged plan view of area A of FIG. 4, according to an embodiment of the present disclosure. FIG. 22 is an enlarged plan view of area A of FIG. 4, according to an embodiment of the present disclosure.

In a description with reference to FIGS. 21 and 22, there may be only differences between positions where the first holes HL1 and the second holes HL2 are provided and planar areas of the first holes HL1 and the second holes HL2 in the description with reference to FIG. 5. Therefore, an overlapping description may be omitted or simplified.

Referring to FIGS. 21 and 22, in an embodiment of the present disclosure, a first planar area of each of the first holes HL1 may be different from a second planar area of each of the second holes HL2.

In an embodiment of the present disclosure, as shown in FIG. 21, the first planar area may be greater than the second planar area. In this case, each of the first holes HL1 may overlap at least two of the second holes HL2 in a plan view. However, the present disclosure is not necessarily limited thereto. For example, even when the first planar area is greater than the second planar area, each of the first holes HL1 may overlap one of the second holes HL2 in a plan view, or might not overlap with the second holes HL2 in a plan view. In addition, in FIG. 21, each of the first holes HL1 is shown to overlap a portion of each of the corresponding second holes HL2 in a plan view, but the present disclosure is not necessarily limited thereto, and each of the first holes HL1 may overlap with each of the corresponding second holes HL2 in a plan view.

In an embodiment of the present disclosure, as shown in FIG. 22, the first planar area may be less than the second planar area. In this case, each of the second holes HL2 may overlap at least two of the first holes HL1 in a plan view. However, the present disclosure is not necessarily limited thereto. For example, even when the first planar area is less than the second planar area, each of the second holes HL2 may overlap one of the first holes HL1 in a plan view, or might not overlap with the first holes HL1 in a plan view. In addition, in FIG. 22, each of the second holes HL2 is shown to overlap a portion of the corresponding first holes HL1 in a plan view, however, the present disclosure is not necessarily limited thereto, and each of the second holes HL2 may overlap each of the corresponding first holes HL1 in a plan view.

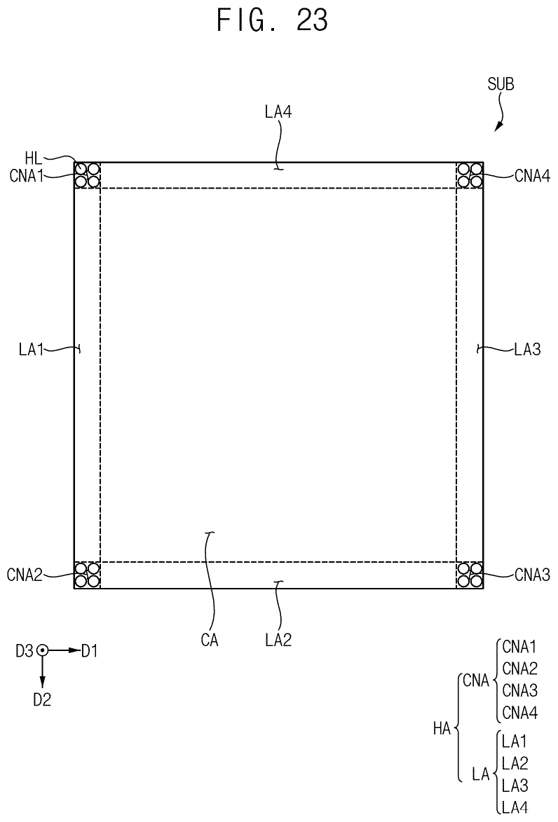

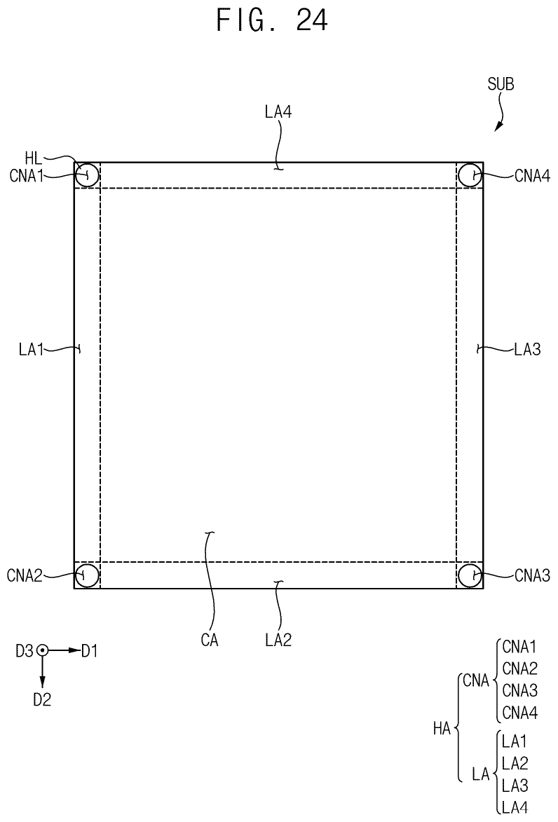

FIG. 23 is an enlarged plan view of the substrate of FIG. 3, according to an embodiment of the present disclosure. FIG. 24 is an enlarged plan view of the substrate of FIG. 3, according to an embodiment of the present disclosure.

Referring to FIGS. 23 and 24, in an embodiment of the present disclosure, the holes HL may be provided only in the corner areas CNA of the substrate SUB. For example, as shown in FIG. 23, two or more holes HL may be provided in each of the corner areas CNA. For another example, as shown in FIG. 24, one hole among the holes HL may be provided in each of the corner areas CNA. For example, the holes HL may be provided only in the corner areas CNA of the substrate SUB, and the holes HL might not be provided in the connection areas LA. By providing the holes HL only in the corner areas CNA, curling of the substrate SUB may be prevented or reduced without excessively deteriorating a durability of the substrate SUB.

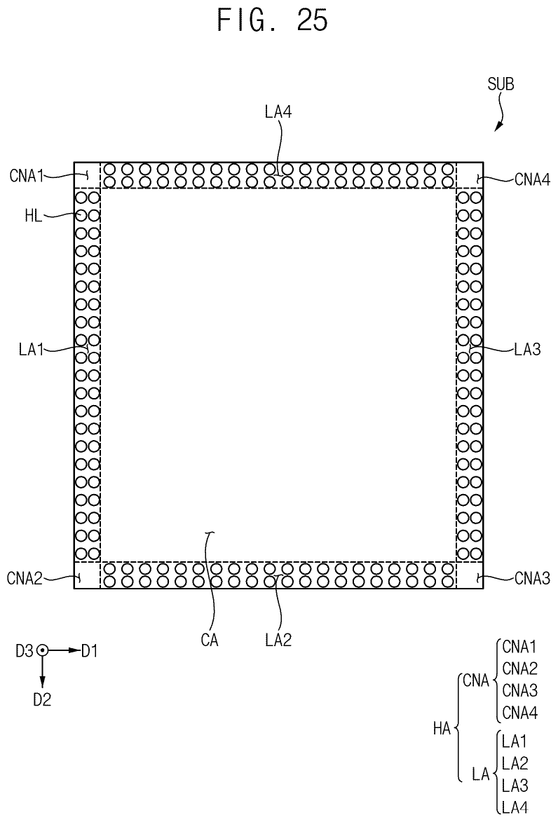

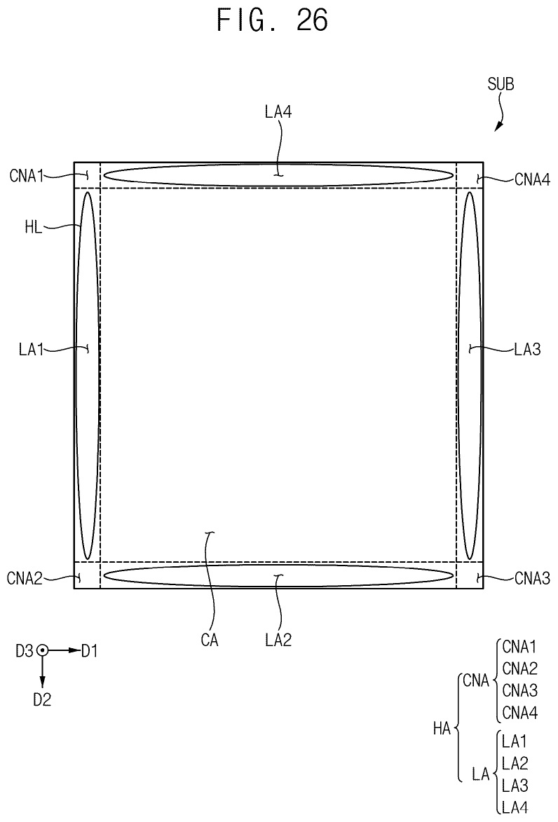

FIG. 25 is an enlarged plan view of the substrate of FIG. 3, according to an embodiment of the present disclosure. FIG. 26 is an enlarged plan view of the substrate of FIG. 3, according to an embodiment of the present disclosure.

Referring to FIGS. 25 and 26, in an embodiment of the present disclosure, the holes HL may be provided only in connection areas LA of the substrate SUB. For example, as shown in FIG. 25, two or more holes HL may be provided in each of the connection areas LA. For another example, as shown in FIG. 26, the holes HL may be respectively provided in the connection areas LA, in a one-to-one manner. For example, a single hole HL, of the holes HL, may be provided in each of the connection areas LA. For example, the holes HL may be disposed only in the connection areas LA of the substrate SUB, and the holes HL might not be disposed in the corner areas CNA. By providing the holes HL only in the connection areas LA, curling of the substrate SUB may be prevented or reduced without excessively deteriorating a durability of the substrate SUB.

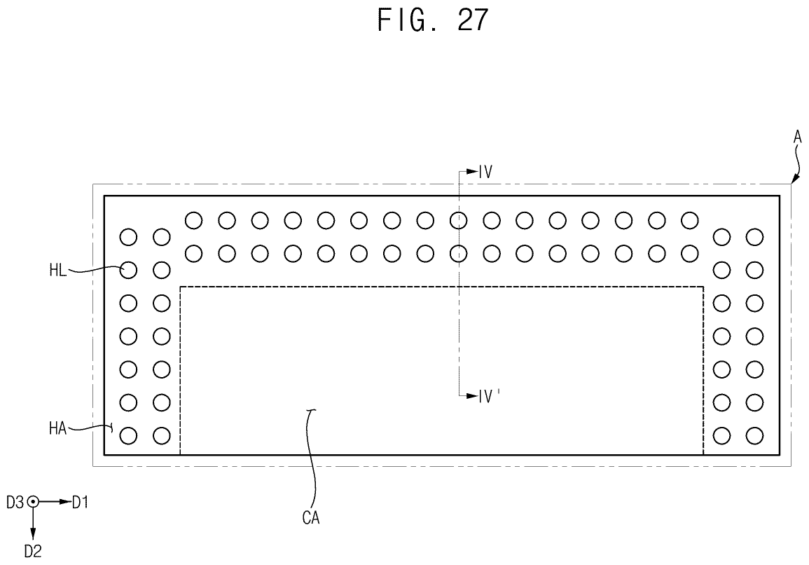

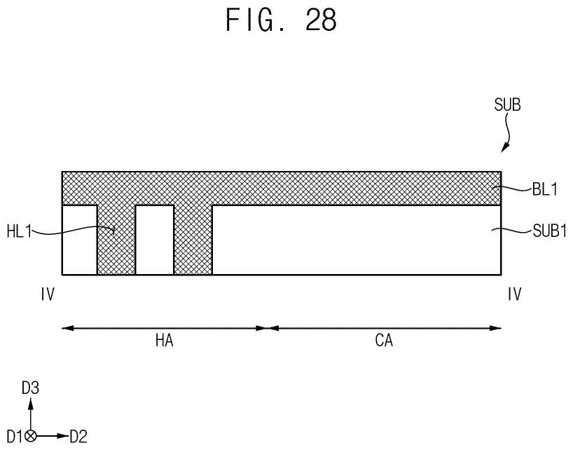

FIG. 27 is an enlarged plan view of area A of FIG. 4, according to an embodiment of the present disclosure. FIG. 28 is a cross-sectional view taken along line IV-IV′ of FIG. 15.

Specifically, a description referring to FIGS. 27 and 28 may be substantially a same as a description referring to FIGS. 5 and 6 except for a layered structure of the substrate SUB. Therefore, overlapping descriptions may be omitted or simplified.

In addition, a manufacturing method of the substrate SUB according to the embodiment with reference to FIGS. 27 and 28 may be substantially a same as a manufacturing method described with reference to FIGS. 7 to 11, except for a layered structure of the substrate SUB. Accordingly, a method of manufacturing the substrate SUB according to the embodiment referring to FIGS. 27 and 28 may be omitted.

Referring to FIGS. 27 and 28, the substrate SUB may have a single-layer structure that includes the first substrate SUB1 and the first barrier layer BL1. The first holes HL1 may be provided in the first substrate SUB 1 having a single-layer structure.

The first barrier layer BL1 may be disposed on the first substrate SUB1. The first barrier layer BL1 may fill the first holes HL1 that are provided in the first substrate SUB1.

According to embodiments of the present disclosure, since the holes HLs are provided in the hole area HA of the substrate SUB, stress that may occur near an edge of the substrate SUB may be reduced. Accordingly, in a manufacturing process of the substrate SUB, when the substrate SUB and the carrier substrate CSUB are separated from each other, a curling phenomenon due to a stress around an edge of the substrate SUB may be prevented. Accordingly, a manufacturing yield of the substrate SUB may be increased and a manufacturing process cost may be reduced accordingly.

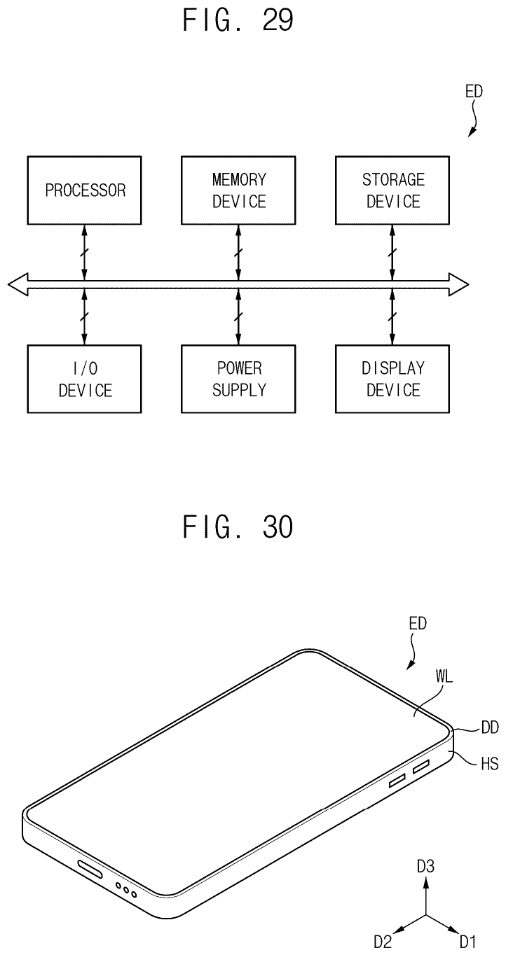

FIG. 29 is a block diagram showing an electronic device according to an embodiment of the present disclosure. FIG. 30 is a perspective view showing the electronic device according to an embodiment of the present disclosure.

Referring to FIGS. 29 and 30, an electronic device ED may include a processor, a memory device, a storage device, an input/output device, a power supply, and a display device. The display device included in the electronic device ED may be the display device DD of FIG. 1. In addition, the electronic device ED may further include several ports capable of communicating with a video card, a sound card, a memory card, a USB device, etc., or communicating with other systems.

The processor may perform specific calculations or tasks. In an embodiment, the processor may be a microprocessor, a central processing unit, an application processor, etc. The processor may be connected to other components through an address bus, a control bus, a data bus, etc. In an embodiment, the processor may also be connected to an expansion bus, such as a Peripheral Component Interconnect (PCI) bus. The processor may output data control signals and image data to the timing controller.

The memory device may store data necessary for an operation of the electronic device ED. For example, the memory device may include nonvolatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), a ferroelectric random access memory (FRAM) device, and/or a volatile memory device such as a dynamic random access memory (DRAM) device, a static random access memory (SRAM) device, a mobile DRAM device, and the like.

The storage device may include a solid state drive (SSD), a hard disk drive (HDD), a CD-ROM, etc. The input/output device may include an input means such as a keyboard, a keypad, a touchpad, a touchscreen, a mouse, etc., and an output means such as a speaker, a printer, etc. In an embodiment, the display device may be included in the input/output device. The power supply may supply power required for the operation of the electronic device ED. The display device may be connected to other components through the buses or other communication links.

In an embodiment, as illustrated in FIG. 29, the electronic device ED may be implemented as a smartphone. The electronic device ED may include a window layer WL, a display device DD, and a housing HS.

The window layer WL may cover the display device DD. For example, the window layer WL may be disposed on the display area (e.g., a display area DA of FIG. 1) of the display device DD to cover the display device DD. Accordingly, the window layer WL may protect the display area of the display device DD where the image is displayed.

The housing HS may surround the display device DD. For example, the display device DD may be accommodated in the housing HS. The housing HS may cover side and bottom of the display device DD. Accordingly, the housing HS may supplement a rigidity of the display device DD and protect the display device DD from external impact.

A functional module such as a camera module or a sensor module may be accommodated in the housing HS. Accordingly, the functional module may be electrically connected to the display device DD and perform a specific function. However, type or arrangement of the functional module according to the embodiments of the present disclosure is not necessarily limited thereto.

However, this is exemplary, and the electronic device ED according to the embodiments of the present disclosure is not necessarily limited thereto. For example, the electronic device ED may be implemented as a mobile phone, a video phone, a smart pad, a smart watch, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

While the present disclosure has been described with reference to embodiments thereof, it will be understood by those of ordinary skill in the art that various changes in form and details may be made thereto without departing from the spirit and scope of the present disclosure.

What is claimed is:

1. A display device comprising:
a light emitting diode;
a transistor disposed below the light emitting diode and electrically connected to the light emitting diode; and
a substrate disposed below the transistor, and including a central area and a hole area that is adjacent to the central area, wherein the substrate includes an organic material and a first substrate, in which first holes are disposed in the hole area.

2. The display device of claim 1, wherein the hole area is adjacent to an edge of the substrate.

3. The display device of claim 1, wherein the substrate further includes a first barrier layer disposed on the first substrate and filling the first holes.

4. The display device of claim 3, wherein the substrate further includes:
a second substrate disposed on the first barrier layer, and including an organic material, wherein the second substrate has second holes disposed in the hole area; and
a second barrier layer disposed on the second substrate and filling the second holes.

5. The display device of claim 4, wherein the second holes expose at least a portion of the first barrier layer.

6. The display device of claim 4, wherein the first holes and the second holes do not overlap each other in a plan view.

7. The display device of claim 4, wherein at least one of the first holes partially overlaps at least one of the second holes in a plan view.

8. The display device of claim 4, wherein at least one of the first holes entirely overlaps at least one of the second holes in a plan view.

9. The display device of claim 4, wherein each of the first holes has a first planar area, and each of the second holes has a second planar area, wherein the first planar area and the second planar area are a same as each other.

10. The display device of claim 4, wherein each of the first holes has a first planar area, and each of the second holes has a second planar area, wherein the first planar area and the second planar area are different from each other.

11. The display device of claim 10, wherein the first planar area is greater than the second planar area.

12. The display device of claim 10, wherein the first planar area is less than the second planar area.

13. The display device of claim 4, wherein each of the first holes and the second holes has a circular planar shape.

14. The display device of claim 1, wherein the hole area includes:
first to fourth corner areas extending from a corner of the central area;
a first connection area connecting the first corner area and the second corner area to each other;
a second connection area connecting the second corner area and the third corner area to each other;
a third connection area connecting the third corner area and the fourth corner area to each other; and
a fourth connection area connecting the fourth corner area and the first corner area to each other.

15. The display device of claim 14, wherein the first holes and the second holes are located in the first to fourth corner areas.

16. The display device of claim 14, wherein the first holes and the second holes are located in the first to fourth connection areas.

17. A method of manufacturing the display device comprising:
forming a first substrate including an organic material, a central area, and a hole area at least partially surrounding the central area on a carrier substrate;
forming first holes in the hole area of the first substrate;
forming a first barrier layer in the first holes and on the first substrate;
forming a second substrate, which includes an organic material, on the first barrier layer;
forming second holes, which expose the first barrier layer, in the second substrate; and
forming a second barrier layer in the second holes and on the second substrate.

18. The method of claim 17, further comprising:
after forming the second barrier layer,
separating the first substrate and the carrier substrate from each other.

19. The method of claim 17, wherein, in forming the first holes and forming the second holes, each of the first holes and the second holes is formed through an etching process.

20. The method of claim 19, wherein the etching process is a dry etching process.

21. An electronic device comprising:
a housing; and
a display device stored in the housing, that displays an image, and including:
a light emitting diode;
a transistor disposed below the light emitting diode and electrically connected to the light emitting diode; and
a substrate disposed below the transistor, and including a central area and a hole area that is adjacent to the central area, wherein the substrate includes an organic material and a first substrate, in which first holes are disposed in the hole area.
